(19) United States
(12) Patent Application Publication
(10) Pub. No.: US 2009/0280439 A1
(43) Pub. Date: Nov. 12, 2009

(54) EXPOSURE APPARATUS, EXPOSURE METHOD, AND DEVICE MANUFACTURING METHOD

(75) Inventor: Yuichi SHIBAZAKI, Kumagaya-shi (JP)

Correspondence Address: OLIFF & BERRIDGE, PLC, P.O. BOX 320850, ALEXANDRIA, VA, 22320-4850, US

(73) Assignee: Nikon Corporation, Tokyo (JP)

(21) Appl. No.: 12/432,998

(22) Filed: Apr. 30, 2009

Related U.S. Application Data
(60) Provisional application No. 61/071,988, filed on May 29, 2008.

(30) Foreign Application Priority Data
Apr. 30, 2008 (JP) 2008-119238

(51) Int. Cl. G03F 7/20; G03B 27/42; G01N 21/41

(52) U.S. Cl. 430/325; 355/53; 355/77; 356/517

(57) ABSTRACT

A light branching unit and a reflecting mirror are fixed to a barrel in a state where the distance between the members is constantly maintained. And, a laser beam from a light source is guided to the light branching unit via an optical fiber, separated to a measurement beam and a reference beam by a beam splitter, and a synthesized light of the measurement beam and the reference beam that reciprocate between the light branching unit and the reflecting mirror in the liquid is then guided to a photodetection system via the optical fiber. And, the measurement beam and the reference beam are made to interfere inside this photodetection system, and a change of an optical path length of the measurement beam is measured based on a photoelectric conversion signal of the interference light. Accordingly, change of a refractive index of the liquid can be optically measured.

### CROSS-REFERENCE TO RELATED APPLICATIONS

This non-provisional application claims the benefit of Provisional Application No. 61/071,988 filed May 29, 2008, the disclosure of which is hereby incorporated herein by reference in its entirety.

### BACKGROUND OF THE INVENTION

1. Field of the Invention

The present invention relates to exposure apparatuses, exposure methods, and device manufacturing methods, and more particularly, to an exposure apparatus and an exposure method in which an object is exposed using an energy beam, and a device manufacturing method using the exposure method.

2. Description of the Background Art

In a lithography process for manufacturing electron devices (microdevices) such as semiconductor devices (such as integrated circuits) and liquid crystal display devices, a projection exposure apparatus, such as, for example, a stepper or a scanner, is used that transfers a pattern formed on a mask (such as a reticle, a photomask and the like) onto a substrate (a wafer, glass plate and the like) on which a sensitive agent such as a resist and the like is applied, via a projection optical system.

Higher integration of semiconductor devices are expected year by year, along with finer device rules (practical minimum line width), and accompanying this, higher resolving power (resolution) is becoming required year by year in a projection exposure apparatus. In order to meet such requirements, exposure apparatus manufacturers have been pursuing to increase numerical aperture (NA) (so-called higher NA) of projection optical systems, together with shortening exposure wavelengths. And, recently, a liquid immersion exposure apparatus that uses a liquid immersion method disclosed in, for example, PCT International Publication No. 99/49504 and the like, in which the exposure wavelength is substantially shortened and the depth of focus also increased (widened) when compared with the depth of focus in the air, has been put to practical use. The liquid immersion exposure apparatus disclosed in, PCT International Publication No. 99/49504, is a local liquid immersion exposure apparatus that performs exposure in a state where a space between a lower surface of a projection optical system (projection lens) and a substrate surface is locally filled with water or liquid such as an organic solvent and the like.

When a substrate is exposed using this kind of liquid immersion exposure apparatus, temperature of the liquid changes by absorption of exposure light and the like, and with the temperature change of the liquid the refractive index changes, and this change of the refractive index changes optical properties (aberration and the like) of an optical system consisting of a projection lens and liquid during exposure. Therefore, it is desirable to measure the temperature change of the liquid, and to adjust the optical properties of the optical system above based on the measurement results. However, the clearance (working distance) between the projection lens and the substrate surface was extremely narrow, which made it difficult to install a thermometer in this section. As a result, it was difficult to measure the temperature change (refractive index change) of the liquid between the projection lens and the substrate surface.

### SUMMARY OF THE INVENTION

According to a first aspect of the present invention, there is provided an exposure apparatus that exposes an object with an energy beam and forms a pattern on the object, the apparatus comprising: a movable body which holds the object and moves along a predetermined plane; an optical system which projects the energy beam on the object; a liquid supply device which supplies liquid at least to a space between the optical system and the object; and a measurement device which optically measures a change of physical quantity related with a refractive index of the liquid existing within the space.

According to this apparatus, the change of physical quantity related with the refractive index of the liquid existing in the space between the optical system and the object can be optically measured by the measurement device. Accordingly, it becomes possible to adjust the optical properties of the optical system according to the physical quantity variation related with the refractive index of the liquid, and therefore, to adjust the optical properties of the projection optical system consisting of the optical system and the liquid and/or the position of the object in the optical axis direction of the projection optical system. As a consequence, by exposing the object with the energy beam via the projection optical system, it becomes possible to form a pattern on the object with good precision.

According to a second aspect of the present invention, there is provided an exposure method in which an energy beam is irradiated on an object held by a movable body that is movable along a predetermined plane via an optical member and liquid, and a pattern is formed on the object, the method comprising: a measurement process in which a change of physical quantity related with a refractive index of the liquid is measured optically; and an adjustment process in which at least one of the optical properties of the projection optical system including the optical member and the liquid, the wavelength of the energy beam, the position of the movable body in a direction orthogonal to the predetermined plane, and the inclination of the movable body with respect to the predetermined plane is adjusted, according to measurement results in the measurement process.

According to this method, the change of physical quantity related with the refractive index of the liquid existing in the space between the optical system and the object is optically measured. And, at least one of the optical properties of the projection optical system including the optical member and the liquid, the wavelength of the energy beam, the position of the movable body in a direction orthogonal to the predetermined plane, and the inclination of the movable body with respect to the predetermined plane is adjusted, according to measurement results in the measurement process. As a consequence, by exposing the object with the energy beam via the projection optical system, it becomes possible to form a pattern on the object with good precision.

According to a third aspect of the present invention, there is provided a device manufacturing method, the method including: a formation process in which a pattern is formed on an object, using the exposure method of the present invention; and a development process in which the object on which the pattern has been formed is developed.

### BRIEF DESCRIPTION OF THE DRAWINGS

In the accompanying drawings:

FIG. 1 is a view schematically showing the configuration of an exposure apparatus related to an embodiment;

FIG. 2 is a view that shows components in the vicinity of a liquid immersion device that are partially sectioned; and

FIGS. 3A and 3B are views showing a schematic configuration of a laser interferometer.

### DESCRIPTION OF THE EMBODIMENTS

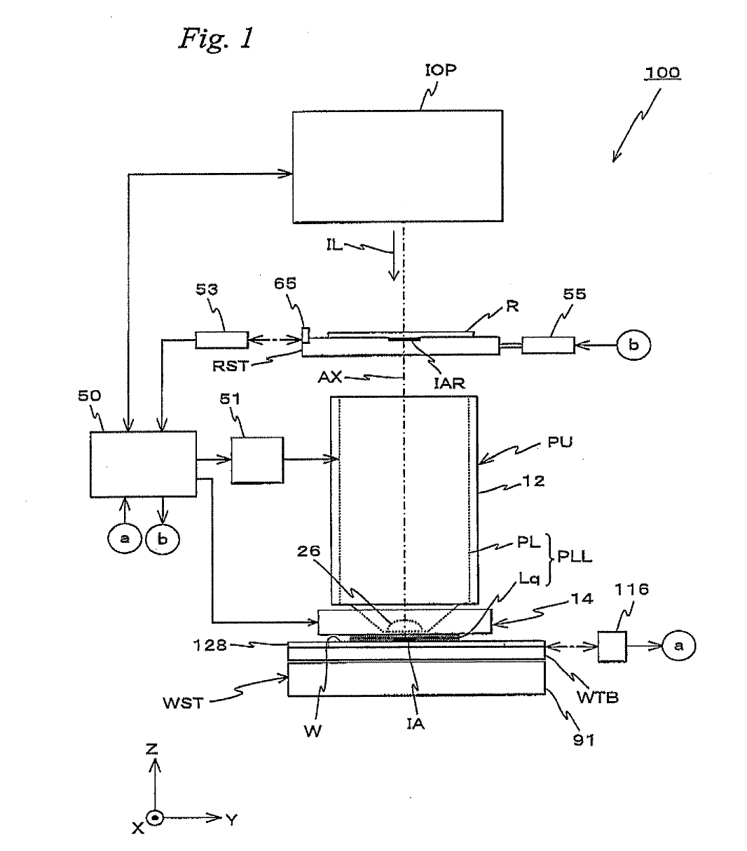

An embodiment of the present invention will be described below, with reference to FIGS. 1 to 3B.

FIG. 1 shows a schematic configuration of an exposure apparatus 100 related to the embodiment. Exposure apparatus 100 is a projection exposure apparatus of the step-and-scan method, namely the so-called scanner. Further, exposure apparatus 100 is a local liquid immersion exposure apparatus that performs exposure in a state where a space between a lower surface of an optical system PL and a wafer W surface is locally filled with a liquid Lq as it will be described later on. In the description below, a direction parallel to an optical axis AX of optical system PL will be described as a Z-axis direction, a direction within a plane orthogonal to the Z-axis direction in which a reticle R and a wafer W are relatively scanned will be described as a Y-axis direction, a direction orthogonal to the Z-axis and the Y-axis will be described as an X-axis direction, and rotational (inclination) directions around the X-axis, the Y-axis, and the Z-axis will be described as θx, θy, and θz directions, respectively.

Exposure apparatus 100 includes an illumination system IOP, a reticle stage RST that holds reticle R which is illuminated by an illumination light for exposure (hereinafter, referred to as “illumination light” or “exposure light”) IL from illumination system IOP, a projection unit PU including optical system PL which projects illumination light IL emitted from reticle R on wafer W, a wafer stage WST, a local liquid immersion device 14 which supplies liquid Lq to the space between wafer W held on wafer stage WST, and a control system and the like of these members. On wafer stage WST, wafer W is mounted.

Illumination system IOP includes a light source, an illuminance uniformity optical system, which includes an optical integrator and the like, a reticle blind and the like (none of which are shown), as is disclosed in, for example, U.S. Patent Application Publication No. 2003/0025890 description and the like. In illumination system IOP, a slit-shaped illumination area which is set on reticle R with the reticle blind is illuminated by illumination light (exposure light) IL with a substantially uniform illuminance. Here, as one example, ArF excimer laser light (with a wavelength of 193 nm) is used as the illumination light IL. Further, as the optical integrator, a fly-eye lens, a rod integrator (an internal reflection type integrator), or a diffractive optical element and the like can be used.

On reticle stage RST, reticle R on which a circuit pattern or the like is formed on its pattern surface (the lower surface in FIG. 1) is fixed, for example, by vacuum chucking. Reticle stage RST is finely drivable within an XY plane by a reticle stage drive section 55 including a linear motor or the like, and is also drivable in a predetermined scanning direction (in this case, the Y-axis direction, which is the lateral direction of the page surface in FIG. 1) at a designated scanning speed.

The positional information (including rotation in the θz direction) of reticle stage RST in the XY plane is constantly detected, for example, at a resolution of around 0.25 nm by a reticle laser interferometer (hereinafter referred to as a “reticle interferometer”) 53, via a movable mirror 65 (the mirrors actually arranged are a Y movable mirror that has a reflection surface which is orthogonal to the Y-axis direction and an X movable mirror that has a reflection surface orthogonal to the X-axis direction). The measurement values of reticle interferometer 53 are sent to a main controller 50, and main controller 50 controls the position (and the speed) of reticle stage RST in the X-axis direction, the Y-axis direction, and the θz direction via reticle stage drive system 55, based on the measurement values of reticle interferometer 53.

Projection unit PU includes a barrel 12, and optical system PL that has a plurality of optical elements which are held in a predetermined positional relation inside barrel 12. As optical system PL, for example, a dioptric system is used that includes a plurality of lenses (lens elements) such as, for example, around 10 to 20, which are disposed, for example, along an optical axis AX direction parallel to the Z-axis direction. Optical system PL is, for example, a both-side telecentric dioptric system that has a predetermined projection magnification (such as one-quarter times, one-fifth times, or one-eighth times). Therefore, in exposure apparatus 100, when illumination light IL from illumination system IOP illuminates an illumination area IAR, illumination light IL that has passed through reticle R which is placed so that its pattern surface substantially coincides with a first plane (an object plane) of optical system PL forms a reduced image of the circuit pattern (a reduced image of a part of the circuit pattern) of the reticle R within illumination area IAR, via optical system PL and liquid Lq (more specifically, projection optical system PLL consisting of optical system PL and liquid Lq), in an area (hereinafter, also referred to as an exposure area) IA conjugate to illumination area IAR on wafer W whose surface is coated with a resist (a sensitive agent) and is placed on a second plane (an image plane) side of the optical system. And, by the synchronous drive of reticle stage RST and wafer stage WST which relatively moves the reticle in the scanning direction (the Y-axis direction) with respect to illumination area IAR (illumination light IL) while relatively moving wafer W in the scanning direction (the Y-axis direction) with respect to exposure area IA (illumination light IL), scanning exposure of a shot area (divided area) on wafer W is performed, and the pattern of reticle R is transferred onto the shot area. Namely, in the present embodiment, the pattern is created on wafer W by illumination system IOP and projection optical system PLL, and that pattern is formed on wafer W by exposing a sensitive layer (resist layer) on wafer W with the illumination light IL.

Of the plurality of lenses that make up optical system PL, the plurality of lenses, for example, on the object plane side (the reticle stage RST side) are movable lenses that can be driven shifting in the Z-axis direction (the optical axis AX direction of optical system PL (and projection optical system PLL)) and drivable in a tilt direction (a θx direction and a θy direction) with respect to the XY plane, for example, by drive elements (not shown) such as piezo elements. And, by each of the movable lenses being driven individually by an image-forming characteristic correction controller 51 based on instructions from main controller 50, various types of optical properties of optical system PL, or to be more precise, projection optical system PLL consisting of optical system PL and liquid Lq, are adjustable, such as, for example, image-forming characteristics (such as magnification, distortion, astigmatism, comatic aberration, spherical aberration, curvature of image plane (image plane distortion)).

Incidentally, because exposure using the liquid immersion method is performed in exposure apparatus 100 of the embodiment, a catodioptric system configured including mirrors and lenses can be used in order to make it easier to satisfy the Petzval condition and to also prevent an increase in size of optical system PL. Further, an image-forming characteristic adjustment device of optical system PL is not limited to a mechanism (an actuator) that moves at least one of the lenses of optical system PL, and can include a device, for example, that makes a wavelength characteristic (center wavelength, wavelength width and the like) of illumination light IL variable.

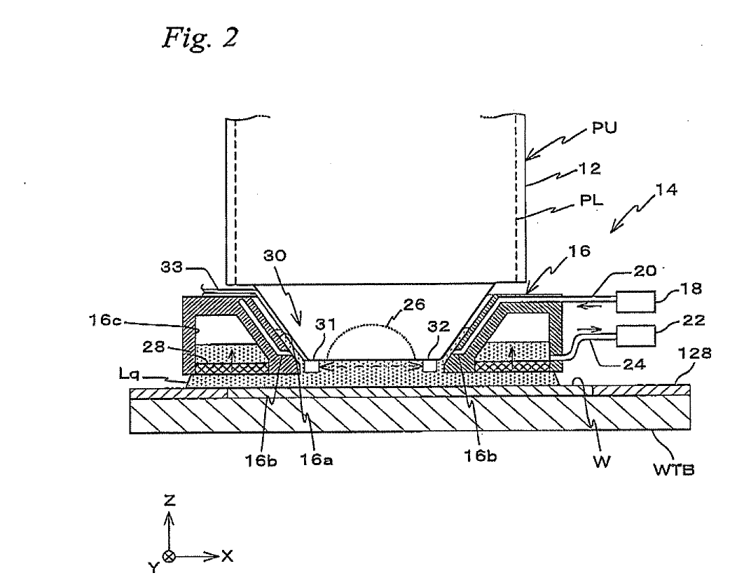

Local liquid immersion device 14 is equipped, as shown in FIG. 2, with a nozzle unit (a local liquid immersion unit) 16, a liquid supply device 18, a liquid supply pipe 20, a liquid recovery device 22, a liquid recovery pipe 24 and the like.

Nozzle unit 16 is placed enclosing the periphery of a lower end portion of barrel 12 holding an optical element closest to the image plane (wafer W side) constituting optical system PL, in this case, lens (hereinafter also referred to as a “tip lens”) 26. Nozzle unit 16 is a rough loop-shaped member that has a through-hole 16a in the center section which is formed so that the inner diameter gradually becomes smaller toward the −Z direction. And, in the vicinity of through-hole 16a, a plurality of liquid supply paths 16b is formed surrounding through-hole 16a (in FIG. 2, however, only two of liquid supply paths 16b formed in the vicinity of the +Y side and the −Y side of through-hole 16a is shown). An opening end of the lower side (the −Z side) of each of the plurality of liquid supply paths 16b is formed on an inner wall surface of through-hole 16a, and an opening end of the upper end is connected to an annular loop-shaped supply path (not shown) arranged along through-hole 16a. One end of liquid supply pipe 20 is connected to this loop-shaped supply path, and the other end of liquid supply pipe 20 is connected to liquid supply device 18.

On the lower surface (a surface on the −Z side) of nozzle unit 16, a liquid recovery opening 16c consisting of an annular recessed section is formed. And to the lower end portion of liquid recovery opening 16c, an annular porous member 28 is attached. To liquid recovery opening 16c, the other end of liquid recovery pipe 24 whose one end is connected to liquid recovery device 22 is connected.

In the embodiment, when wafer W is under projection unit PU as shown in FIG. 2, liquid is supplied in the space between tip lens 26 and wafer W from liquid supply device 18, via liquid supply pipe 20, the loop-shaped supply path (not shown), and the plurality of liquid supply paths 16b, under instructions from main controller 50 (refer to FIG. 1). Further, under instructions from main controller 50, the same amount of liquid as the amount of liquid to be supplied is collected by liquid recovery device 22 from between tip lens 26 and wafer W, via liquid recovery opening 16c and liquid recovery pipe 24. This allows a constant quantity of liquid Lq to be held in the space between tip lens 26 and wafer W. A liquid immersion area (liquid immersion space) formed by this liquid Lq has a circular shape in a planar view (when viewed from the +Z direction). In this case, liquid Lq held in the space between tip lens 26 and wafer W is constantly replaced.

Incidentally, in the embodiment, as liquid Lq, pure water that transmits the ArF excimer laser beam (light having a wavelength of 193 nm), which is used as illumination light IL, is to be used. Refractive index n of the pure water with respect to the ArF excimer laser beam is around 1.44, and in the pure water the wavelength of illumination light IL is 193 nm×1/n, shorted to around 134 nm.

In the embodiment, for example, tip lens 26 is made of fluorite which has a high affinity with the pure water so that the lower surface (a liquid contact surface) of tip lens 26 is lyophilic (hydrophilic) with liquid Lq, and for example, a predetermined lyophilic treatment is applied to the lower surface of nozzle unit 16 so that the lower surface (a liquid contact surface) of nozzle unit 16 is lyophilic (hydrophilic) with liquid Lq. As the lyophilic treatment of nozzle unit 16, for example, a treatment which applies a lyophilic material such as MgF₂, Al₂O₃, and SiO₂ to the lower surface (the liquid contact surface) of nozzle unit 16 can be employed. Further, in the case of using pure water as liquid Lq as in the embodiment, a treatment of providing a thin film made of a material (e.g., alcohol) that has a molecular structure with a large polarity can be employed as the lyophilic treatment, using the point that pure water has a large polarity. Incidentally, tip lens 26 can be made of fluorite, which has a high affinity with water. Further, on the lower surface of tip lens 26, a lyophilic treatment similar to nozzle unit 16 described above can be applied.

As described, because the lower surface of tip lens 26 and the lower surface of nozzle unit 16 are lyophilic, the liquid immersion area of liquid Lq can be formed favorably between the lower surface of tip lens 26 and the lower surface of nozzle unit 16, and the upper surface of wafer W and the upper surface of a liquid repellent plate which will be described later on, using a surface tension of liquid Lq.

In exposure apparatus 100 of the embodiment, a laser interferometer 30 is arranged that includes a light branching unit 31 and a reflecting mirror 32 respectively fixed at a predetermined positional relation on the lower surface of barrel 12, which holds optical system PL.

Light branching unit 31 and reflecting mirror 32, in this case, are placed apart in the X-axis direction by a predetermined distance, such as, for example, around 50 mm, with an irradiation area of illumination light IL emitted from tip lens 26 in between. Further, light branching unit 31 and reflecting mirror 32 are each placed substantially at the center (substantially coinciding with the center of exposure area IA in the Y-axis direction in the embodiment) of optical system PL in the Y-axis direction (scanning direction).

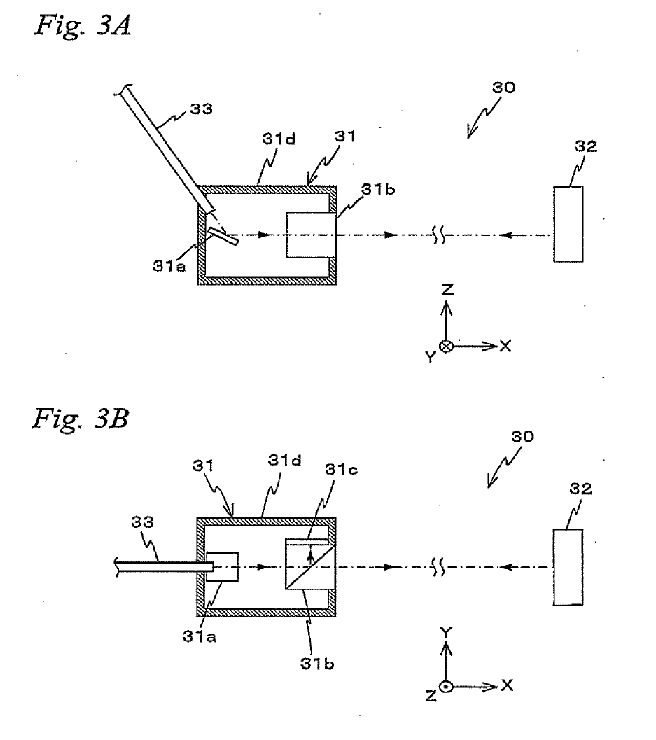

FIG. 3A shows a schematic configuration of laser interferometer 30 when viewed from the −Y direction, whereas FIG. 3B shows a schematic configuration of laser interferometer 30 when viewed from the +Z direction. As it can be seen when viewing FIGS. 3A and 3B together, light branching unit 31 has a deflection mirror (bending mirror) 31a, a beam splitter 31b, a reference mirror (a fixed mirror) 31c made up of a plane mirror, and a housing 31d.

Beam splitter 31b, as shown in FIG. 3B, is placed in a state where its separation plane is inclined at an angle of 45 degrees with respect to an XZ plane and a YZ plane, and also serves as a part of a side wall on the +X side of housing 31d that has a rectangular solid shape. As a matter of course, a part of the side wall on the +X side of housing 31d can be made of a material which has the same refractive index, coefficient of thermal expansion and the like as beam splitter 31b, and beam splitter 31b can be completely housed inside of housing 31d. As beam splitter 31b, both a polarization beam splitter and a half prism can be used.

Reference mirror 31c is fixed integrally on a surface on the +Y side of beam splitter 31b.

To a side wall on the −X side of housing 31d, for example, one end of a dual-core optical fiber 33, which can perform bidirectional optical transmission, is inserted in an air-tight state at a predetermined angle with respect to the XY plane. The attitude of optical fiber 33 and deflection mirror 31a is set so that the traveling direction of light guided by optical fiber 33 is deflected to the +X direction by deflection mirror 31a.

On a side on the other end of optical fiber 33, although it is not shown, a branching section is provided, and to one end of the branching section, a photodetection system is optically connected, and to the other end of the branching section, a light source such as, for example, a semiconductor laser or other laser light sources, is optically connected via an isolator which prevents the backflow of light.

The photodetection system has a polarizer and a light receiving element (e.g., a photomultiplier tube (PMT) and the like).

According to laser interferometer 30 configured in the manner described above, a laser beam emitted from the light source (not shown) is guided inside housing 31d by optical fiber 33, deflected in the +K direction by deflection mirror 31a, and is incident on beam splitter 31b.

The laser beam which is incident on beam splitter 31b diverges into a measurement beam which passes through the separation plane of beam splitter 31b and travels in the +X direction, and a reference beam which is reflected off the separation plane ands travels in the +Y direction.

The measurement beam traveling in the +X direction is reflected off the reflection surface of reflecting mirror 32, and proceeds its original path in an opposite direction, returning to optical fiber 33.

Meanwhile, the reference beam is reflected off the reflection surface of reference mirror 31c, and then is reflected again on the separation plane of beam splitter 31b and is synthesized coaxially with the measurement beam, and returns to optical fiber 33.

And, the synthesized light of the measurement beam and the reference beam entering optical fiber 33 enters the photodetection system via the branching section of optical fiber 33 previously described, and the polarized direction is arranged by the polarizer, and then the beams interfere with each other to become an interference light which is detected by the light receiving element, and is converted into an electrical signal in accordance with the intensity of the interference light, and a processing similar to the normal processing of a Michelson interferometer is performed in a signal processing circuit (not shown). Then, main controller 50, which receives an output signal (hereinafter shortly referred to as an output) from the signal processing circuit, measures a change in the optical path length of the measurement beam.

The interference state of the interference light of the reference beam and the measurement beam incident on the light receiving element changes according to the optical path length of the measurement beam, because the optical path difference of the measurement beam and the reference beam, namely, the optical path length of the reference beam is substantially constant. In the embodiment, light branching unit 31 and reflecting mirror 32 are fixed to barrel 12 in a state where the physical distance between the two is constantly maintained, and the measurement beam travels through liquid Lq. Therefore, the optical path length (the optical distance between light branching unit 31 and reflecting mirror 32) of the measurement beam changes according to the change of the refractive index of liquid Lq, and as a result, the intensity of the interference light will change according to the change of the refractive index of liquid Lq. Accordingly, in the embodiment, by monitoring the output from the signal processing circuit which processed the electrical signals from the light receiving element, the change of the refractive index of liquid Lq (the change of temperature of liquid Lq according to this change) can be detected. Incidentally, it is known in general that if pressure is constant, the refractive index of the liquid is inversely proportional (decreases when the temperature rises) to the temperature.

Referring back to FIG. 1, on the bottom surface of wafer stage WST, for example, a vacuum preload type hydrostatic air bearing (hereinafter referred to as an air bearing) is provided in a plurality of places. By the plurality of air bearings, wafer stage WST is supported in a non-contact manner via a clearance of around several μm on a base board (not shown).

Wafer stage WST, for example, includes a stage main section 91, which is movable by a plurality of linear motors within the XY plane, or more specifically, in the X-axis direction, the Y-axis direction, and the θz direction, and a wafer table WTB, which is mounted on stage main section 91 via a Z-leveling mechanism (not shown) (such as a voice coil motor) and is finely driven relative to stage main section 91 in the Z direction, the ex direction, and the θy direction.

On wafer table WTB, a wafer holder (not shown) that holds wafer W by vacuum suction or the like is arranged. Further, on the upper surface of wafer table WTB, a liquid repellent plate 128 is arranged, which forms a substantially flush surface with wafer W mounted on the wafer holder, has a rectangular outer shape (contour), and has a circular opening slightly larger than the wafer holder which is formed in the center portion.

To the +Y edge surface and the −X edge surface of wafer table WTB, mirror-polishing is applied, respectively, and reflection surfaces are formed. On these reflection surfaces, interferometer beams (measurement beams) from an X-axis interferometer and a Y-axis interferometer (in FIG. 1, only a Y-axis interferometer 116 is shown) for measuring the wafer stage position that configure an interferometer system are irradiated, and by receiving the reflection beams with each interferometer, displacement from a reference position (in general, a mirror surface of a fixed mirror provided on a side surface of projection unit PU serves as a reference surface) of each reflection surface is measured, and the measurement values are supplied to main controller 50. This allows main controller 50 to measure the two-dimensional position of wafer stage WST.

In exposure apparatus 100 of the embodiment, although it is omitted in the drawings, a multipoint focal position detecting system by an oblique incident method is further arranged, which is composed of an irradiation system and a photodetection system similar to the ones disclosed in, for example, Kokai (Japanese Unexamined Patent Application Publication) No. 06-283403 (the corresponding U.S. Pat. No. 5,448,332) and the like.

The control system in the exposure apparatus of the embodiment is mainly configured of main controller 50 composed of a microcomputer (or a workstation) that performs overall control of the entire apparatus.

In exposure apparatus 100 of the embodiment configured in the manner described above, main controller 50 performs exposure by a step-and-scan method on wafer W on wafer stage WST, based on results of wafer alignment and the like, such as, for example, enhanced global alignment (EGA) that has been performed beforehand. This exposure by the step-and-scan method is performed by repeating a movement operation between shots in which wafer stage WST is moved to a scanning starting position (acceleration starting position) to expose each shot area on wafer W, and a scanning exposure operation previously described in which the pattern of reticle R is transferred onto each shot area by the scanning exposure method.

FIG. 1 shows a state in which an exposure operation by the step-and-scan method of wafer W on wafer stage WST is performed.

Then, at the stage when exposure of wafer W has been completed, main controller 50 begins an operation to drive wafer stage WST to a predetermined wafer exchange position, based on the measurement values of the interferometer system including Y-axis interferometer 116. When wafer stage WST is driven by main controller 50 in the manner described above, liquid Lq held in the space between tip lens 26 of projection unit PU and wafer W moves from an area above wafer W to an area above liquid repellent plate 128 with the movement of the wafer stage WST, so that liquid Lq is held in a space between a predetermined area provided in a part of liquid repellent plate 128 and tip lens 26.

Main controller 50 exchanges the wafer from wafer W on wafer stage WST to a wafer subject to the next exposure at the wafer exchange position. Then, main controller 50 performs wafer alignment and exposure operation by the step-and-scan method on a new wafer, and sequentially transfers the reticle pattern on a plurality of shot areas on the wafer. Hereinafter, a similar operation is executed repeatedly.

In exposure apparatus 100 of the embodiment, during the scanning exposure previously described, main controller 50 performs a focus leveling control of wafer W in which wafer table WTB is finely driven in the Z-axis direction, the θx direction and the θz direction so as to make the wafer W surface corresponding to exposure area IA coincide within the range of the depth of focus of optical system PL as much as possible, based on an output (hereinafter shortly referred to simply as an output of laser interferometer 30) from a signal processing circuit that has simultaneously processed an output of the multiple point focal point position detection system previously described and electrical signals output by the light receiving element of laser interferometer 30.

In concurrence with the focus leveling control previously described, main controller 50 can drive at least one movable lens via image-forming characteristic correction controller 51, based on the output of laser interferometer 30, and can adjust at least one image-forming characteristic of projection optical system PLL consisting of optical system PL and liquid Lq, such as, for example, magnification, distortion, astigmatism, comatic aberration, spherical aberration, and curvature of image plane (image plane distortion). When main controller 50 adjusts the image-forming characteristic described above, in this case, in addition to, or instead of the drive of the movable lens, the wavelength of illumination light IL can be adjusted.

A relation between the phenomenon that the output of laser interferometer 30 shows, or more specifically, the change (more specifically, the change of the refractive index of liquid Lq) of the optical path length of the measurement beam of laser interferometer 30 in liquid Lq, and the optical properties of projection optical system PLL, is obtained beforehand by an experiment (including a simulation), and is stored in a memory (not shown) of main controller 50.

As described above, in exposure apparatus 100 related to the embodiment, because the optical path of the measurement beam of laser interferometer 30 is set so as to intersect the optical path of exposure light IL which has passed through tip lens 26, main controller 50 can measure the refractive index of liquid Lq on the optical path of exposure light IL, or to be more precise, the average refractive index (change) of the liquid on the optical path of the measurement beam from branching unit 31 of laser interferometer 30, based on the output from the signal processing circuit that has processed the output from the light receiving element of laser interferometer 30.

Further, according to exposure apparatus 100 related to the embodiment, during the exposure operation, focus leveling control to make the wafer W surface corresponding to exposure area IA coincide within the range of the depth of focus of optical system PL as much as possible is performed by main controller 50, based on the output of the multiple point focal point position detection system and the output of laser interferometer 30.

In a local liquid immersion exposure apparatus, when performing the focus leveling control described above, it is necessary to measure the temperature change of liquid Lq at a sensitivity of around 1/1000 degrees Celsius, however, when the temperature of liquid Lq changes by around 1/1000 degrees Celsius, the optical path length of the measurement beam of laser interferometer 30 changes by around 10 nm. Because the resolution is equal to or less than around 1 nm in an interferometer using the laser beam in general, in exposure apparatus 100, it is possible to measure the temperature change of liquid Lq at a sensitivity of around 1/10000 degrees Celsius. Because of this, focus leveling control can be performed with high accuracy, and it becomes possible to form a pattern on each shot area on wafer W with good precision.

Further, in exposure apparatus 100 of the embodiment, because only light branching unit 31 and reflecting mirror 32 which can be produced remarkably small when compared with a temperature sensor have to be attached to the lower end surface of optical system PL, the temperature (refractive index) of liquid Lq can be measured without the flow of liquid Lq on the optical path of the exposure light IL being hardly blocked.

Incidentally, in the embodiment above, while the case has been described where exposure apparatus 100 is equipped with laser interferometer 30 having light branching unit 31 and reflecting mirror 32 that make a pair, the present invention is not limited to this. For example, a plurality of sets of light branching unit 31 and reflecting mirror 32 can be provided, and these members can be placed at different positions (the positions can be either crossing exposure area IA, or outside exposure area IA) in the scanning direction of the lower surface of barrel 12 of optical system PL and can measure the change (the change of the refractive index (temperature) of liquid Lq) of the optical path length of the measurement beam at each position. In this case, main controller 50 can measure the change (the change of refractive index (temperature) of liquid Lq) of the optical path length of the measurement beam between two points, which are each on a plurality of measurement optical paths, at a timing according to the movement of wafer stage WST in the scanning direction. In this case, main controller 50 can perform pre-read control of the surface position of the wafer based on the refractive index change of liquid Lq as in the pre-read control of the wafer surface position using the multiple point focal point position detection system, for example, taking into consideration the control delay of tilt drive of wafer table WTB. Further, for example, measurement errors of the refractive index of liquid Lq on exposure area IA of wafer W moving in the Y-axis direction can be compensated by a plurality of measurement results.

Besides this, the plurality of sets of light branching unit 31 and reflecting mirror 32 can be placed apart in the Z-axis direction or the X-axis direction.

Incidentally, in the embodiment above, while light branching unit 31 and reflecting mirror 32 of laser interferometer 30 were fixed to barrel 12, as well as this, light branching unit 31 and reflecting mirror 32 of laser interferometer 30 can be supported, for example, by nozzle unit 16 or a support member (not shown) (e.g., metrology frame and the like). The important thing is that the optical path of the measurement beam from light branching unit 31 should be set in liquid Lq.

Further, in the embodiment above, while light branching unit 31 and reflecting mirror 32 of laser interferometer 30 are placed with the optical path of exposure light IL in between, the optical path of the measurement beam does not necessarily have to intersect with the optical path of exposure light IL.

Further, in the embodiment above, light branching unit 31 and reflecting mirror 32 of laser interferometer 30 were fixed to barrel 12, and light branching unit 31, the light source, and the photodetection system were optically connected by the dual-core optical fiber 33. However, as well as this, a configuration (such a configuration can be realized by using a polarization beam splitter as beam splitter 31b, and placing a quarter-wave plate appropriately) of a light branching unit in which the optical path of the laser beam that enters light branching unit 31 from the light source and the optical path of the synthesized light returning from branching unit 31 to the photodetection system are separate optical paths can be employed, and the light branching unit and reflecting mirror 32 can be fixed to barrel 12 while the light source and the photodetection system are fixed to the lower surface of nozzle unit 16, so that a so-called air transmission (in this case, transmission through liquid Lq) of light is performed between the light source and the light branching unit, and between the light branching unit and the photodetection system.

Further, in the embodiment above, while light branching unit 31 and reflecting mirror 32 of laser interferometer 30 are placed along the X-axis direction (a direction orthogonal to the scanning direction), as well as this, light branching unit 31 and reflecting mirror 32 can be placed along the Y-axis direction.

Incidentally, in the embodiment above, while the focus leveling control of wafer W during scanning exposure and the like was performed, based on the output of laser interferometer 30 and the output of the multiple point focal point position detection system, the multiple point focal point position detection system does not necessarily have to be used in the focus leveling control of wafer W. That is, a control similar to the description above can be performed by measuring the positional information (surface position information) of the wafer surface related to the optical direction of the projection optical system in advance (prior to exposure, such as for example, at the time of wafer alignment), using a surface position sensor and the like, with the surface position information (or the Z positional information of the wafer table which is measured using a Z interferometer and the like) of the wafer table surface measured using a Z sensor serving as a reference, and using the measurement information and the actual measurement information by the Z sensor (or the Z interferometer) at the time of exposure.

Incidentally, in the embodiment above, while a nozzle unit that has a lower surface where the wafer faces was used, a configuration having multiple nozzles as disclosed in, for example, PCT International Publication No. 99/49504, can also be employed. The point is that any configuration can be employed, as long as liquid can be supplied in the space between the optical member (tip lens) 191 at the lowest end constituting optical system PL and wafer W, and a part of an apparatus used to optically measure the change of physical quantity related to the refractive index of the liquid existing in the liquid immersion area formed by the liquid can be placed in a state where at least a part of the apparatus is in contact with the liquid immersion area. For example, the liquid immersion mechanism disclosed in PCT International Publication No. 2004/053955, and the liquid immersion mechanism disclosed in the EP Patent Publication No. 1420298 can also be applied to the exposure apparatus of the embodiment.

Incidentally, in the embodiment, while the case has been described where wafer stage WST includes stage main section 91 and wafer table WTB, a single stage that can move in six degrees of freedom can also be employed as wafer stage WST. Incidentally, instead of a reflection surface, a movable mirror consisting of a plane mirror can be arranged in wafer table WTB.

Incidentally, in the embodiment above, pure water (water) was used as the liquid, however, it is a matter of course that the present invention is not limited to this. As the liquid, a chemically stable liquid that has high transmittance to illumination light IL and is safe to use, such as a fluorine-containing inert liquid can be used. As the fluorine-containing inert liquid, for example, Fluorinert (the brand name of 3M United States) can be used. The fluorine-containing inert liquid is also excellent from the point of cooling effect. Further, as the liquid, liquid which has a refractive index higher than pure water (a refractive index is around 1.44), for example, liquid having a refractive index equal to or higher than 1.5 can be used. As this type of liquid, for example, a predetermined liquid having C—H binding or O—H binding such as isopropanol having a refractive index of about 1.50, glycerol (glycerin) having a refractive index of about 1.61, a predetermined liquid (organic solvent) such as hexane, heptane or decane or the like can be cited. Alternatively, a liquid obtained by mixing arbitrary two or more of these liquids may be used, or a liquid obtained by adding (mixing) the predetermined liquid to (with) pure water can be used. Alternatively, as the liquid, a liquid obtained by adding (mixing) base or acid such as H⁺, Cs⁺, K⁺, Cl⁻, SO₄²⁻, or PO₄²⁻ to (with) pure water can be used. Moreover, a liquid obtained by adding (mixing) particles of Al oxide or the like to (with) pure water can be used. These liquids can transmit ArF excimer laser light. Further, as the liquid, liquid, which has a small absorption coefficient of light, is less temperature-dependent, and is stable to an optical system (tip lens) and/or a photosensitive agent (or a protection film (top coat film), an antireflection film, or the like) coated on the surface of a wafer, is preferable. Further, in the case an F₂ laser is used as the light source, fomblin oil can be selected.

Furthermore, in the embodiment above, while the exposure apparatus was equipped with all of local liquid immersion device 14, the exposure apparatus does not have to be equipped with a part of (for example, liquid supply device and/or liquid recovery device and the like) local liquid immersion device 14, and these parts can be substituted by the equipment available in the factory where the exposure apparatus is installed.

Further, in the embodiment above, the case has been described where the present invention is applied to a scanning exposure apparatus by a step-and-scan method or the like. However, the present invention is not limited to this, but may also be applied to a static exposure apparatus such as a stepper. Moreover, the present invention can also be applied to a multi-stage type exposure apparatus equipped with a plurality of wafer stages, as is disclosed in, for example, Kokai (Japanese Unexamined Patent Application Publications) No. 10-163099 and No. 10-214783 (the corresponding U.S. Pat. No. 6,590,634), Kohyo (published Japanese translation of International Publication for Patent Application) No. 2000-505958 (the corresponding U.S. Pat. No. 5,969,441), the U.S. Pat. No. 6,208,407, and the like. In this case, by constantly placing either of the wafer stages interchangeably below projection optical system PLL, the liquid can be held in the space between the measurement stage and the liquid immersion unit (optical system PL). This eliminates the operation of recovering and supplying the liquid each time the wafer is exchanged, which can improve the throughput, and can also prevent water stains (water marks) from being generated on the tip lens surface of optical system PL.

Further, in the embodiment above, a measurement stage can be arranged separately from the wafer stage as disclosed in, for example, PCT International Publication No. WO2005/074014, PCT International Publication No. WO1999/23692, U.S. Pat. No. 6,897,963 and the like, and the liquid can be held in the space between the measurement stage and the liquid immersion unit by placing the measurement stage directly under projection optical system PL in exchange with the wafer stage at times such as the exchange operation of the wafer. In this case as well, the operation of recovering and supplying the liquid each time the wafer is exchanged is not necessary, which can improve the throughput, and can also prevent water marks from being generated on the tip lens surface.

Further, the magnification of the projection optical system in the exposure apparatus in the embodiment above is not only a reduction system, but also may be either an equal magnifying system or a magnifying system, and the projection optical system can be not only a refraction system or a catodioptric system, but also a reflection system, and the projected image can either be an inverted image or an upright image.

Further, in the embodiment above, a transmissive type mask (reticle), which is a transmissive substrate on which a predetermined light shielding pattern (or a phase pattern or a light attenuation pattern) is formed, is used. Instead of this reticle, however, as is disclosed in, for example, U.S. Pat. No. 6,778,257 description, an electron mask (which is also called a variable shaped mask, and includes, for example, a DMD (Digital Micromirror Device) that is a type of a non-emission type image display device (spatial light modulator) or the like) on which a light-transmitting pattern, a reflection pattern, or an emission pattern is formed according to electronic data of the pattern that is to be exposed can also be used.

Moreover, the present invention can also be applied to an exposure apparatus that synthesizes two reticle patterns via a projection optical system and almost simultaneously performs double exposure of one shot area by one scanning exposure, as is disclosed in, for example, Kohyo (published Japanese translation of International Publication for Patent Application) No. 2004-519850 (the corresponding U.S. Pat. No. 6,611,316).

Incidentally, an object on which a pattern is to be formed (an object subject to exposure to which an energy beam is irradiated) in the embodiment above is not limited to a wafer, but may be other objects such as a glass plate, a ceramic substrate, a film member, or a mask blank.

The use of the exposure apparatus is not limited only to the exposure apparatus for manufacturing semiconductor devices, but the present invention can also be widely applied to an exposure apparatus for transferring a liquid crystal display device pattern onto a rectangular glass plate and an exposure apparatus for producing organic ELs, thin magnetic heads, imaging devices (such as CCDs), micromachines, DNA chips, and the like. In addition to fabricating microdevices like semiconductor devices, the present invention can also be adapted to an exposure apparatus that transfers a circuit pattern to a glass substrate, a silicon wafer, or the like in order to fabricate a reticle or a mask used by a visible light exposure apparatus, an EUV exposure apparatus, an X-ray exposure apparatus, an electron beam exposure apparatus, and the like.

Incidentally, the disclosures of all publications, the Published PCT International Publications, the U.S. patent applications and the U.S. patents that are cited in the description so far related to exposure apparatuses and the like are each incorporated herein by reference.

Incidentally, semiconductor devices are manufactured through the steps of; a step where the function/performance design of the device is performed, a step where a reticle based on the design step is manufactured, a step where a wafer is manufactured from silicon materials, a lithography step where the pattern formed on a mask is transferred onto an object such as the wafer by the exposure apparatus in the embodiment above, a development step where the wafer that has been exposed is developed, an etching step where an exposed member of an area other than the area where the resist remains is removed by etching, a resist removing step where the resist that is no longer necessary when etching has been completed is removed, a device assembly step (including a dicing process, a bonding process, the package process), inspection steps and the like. In this case, in the lithography step, because the device pattern is formed on the wafer by executing the exposure method described above using the exposure apparatus in the embodiment above, productivity of a highly integrated device can be improved.

While the above-described embodiment of the present invention is the presently preferred embodiment thereof, those skilled in the art of lithography systems will readily recognize that numerous additions, modifications, and substitutions may be made to the above-described embodiment without departing from the spirit and scope thereof. It is intended that all such modifications, additions, and substitutions fall within the scope of the present invention, which is best defined by the claims appended below.

1. An exposure apparatus that exposes an object with an energy beam and forms a pattern on the object, the apparatus comprising:
a movable body which holds the object and moves along a predetermined plane;
an optical system which projects the energy beam on the object;
a liquid supply device which supplies liquid at least to a space between the optical system and the object; and
a measurement device which optically measures a change of physical quantity related with a refractive index of the liquid existing within the space.

2. The exposure apparatus according to claim 1 wherein
the measurement device measures the change of physical quantity related with the refractive index of the liquid between two points where at least a part of a path of the energy beam is included.

3. The exposure apparatus according to claim 2 wherein
the physical quantity is an optical path length of a measurement beam between the two points.

4. The exposure apparatus according to claim 2 wherein
the two points are located on a measurement optical path which is roughly parallel to the predetermined plane of within the liquid.

5. The exposure apparatus according to claim 4 wherein
the movable body relatively moves in a scanning direction within the predetermined plane with respect to the energy beam for formation of a pattern to the object, and
the measurement optical path is orthogonal to the scanning direction within a plane parallel to the predetermined plane.

6. The exposure apparatus according to claim 5 wherein
the measurement device measures the change of physical quantity related with the refractive index of the liquid between two points, which are each on a plurality of measurement optical paths spaced apart in the scanning direction.

7. The exposure apparatus according to claim 6 wherein
the measurement device measures the change of the physical quantity between each of the two points on the plurality of measurement optical paths, at a timing according to a movement of the movable body in the scanning direction.

8. The exposure apparatus according to claim 1, the apparatus further comprising:
an adjustment device which adjusts at least one of optical properties of a projection optical system including the optical system and the liquid and a wavelength of the energy beam, based on measurement results of the measurement device.

9. The exposure apparatus according to claim 1, the apparatus further comprising:
a controller which controls at least one of a position of the movable body in a direction orthogonal to the predetermined plane and an inclination with respect to the predetermined plane, based on measurement results of the measurement device.

10. The exposure apparatus according to claim 1 wherein
the measurement device is an interferometer which irradiates a measurement beam perpendicularly on a reflection surface of the projection optical system arranged in the vicinity of one end of an opposing surface that faces the object.

11. The exposure apparatus according to claim 10 wherein
the interferometer has an optical unit including a branching element arranged in the vicinity of the other end of the opposing surface of the projection optical system that separates a laser beam into the measurement beam and a reference beam.

12. The exposure apparatus according to claim 11 wherein
the interferometer includes an optical fiber which guides the laser beam to the optical unit.

13. An exposure method in which an energy beam is irradiated on an object held by a movable body that is movable along a predetermined plane via an optical member and liquid, and a pattern is formed on the object, the method comprising:
a measurement process in which a change of physical quantity related with a refractive index of the liquid is measured optically; and
an adjustment process in which at least one of optical properties of the projection optical system including the optical member and the liquid, wavelength properties of the energy beam, a position of the movable body in a direction orthogonal to the predetermined plane, and an inclination of the movable body with respect to the predetermined plane is adjusted, according to measurement results in the measurement process.

14. The exposure method according to claim 13 wherein
in the measurement process, the change of physical quantity related with the refractive index of the liquid between two points where at least a part of a path of the energy beam is included.

15. The exposure method according to claim 14 wherein
the physical quantity is an optical path length of a measurement beam between the two points.

16. The exposure method according to claim 14 wherein
the two points are located on a measurement optical path which is roughly parallel to the predetermined plane of within the liquid.

17. The exposure method according to claim 16 wherein
the movable body relatively moves in a scanning direction within the predetermined plane with respect to the energy beam for formation of a pattern to the object, and
the measurement optical path is orthogonal to the scanning direction within a plane parallel to the predetermined plane.

18. The exposure method according to claim 17 wherein
in the measurement process, the change of physical quantity related with the refractive index of the liquid is measured between two points, which are each on a plurality of measurement optical paths spaced apart in the scanning direction.

19. The exposure method according to claim 18 wherein
in the measurement process, the change of the physical quantity is measured between each of the two points on the plurality of measurement optical paths, at a timing according to a movement of the movable body in the scanning direction.

20. A device manufacturing method, the method including:
a formation process in which a pattern is formed on an object, using the exposure method according to claim 13; and
a development process in which the object on which the pattern has been formed is developed.
